(19) United States
(12) Patent Application Publication
(10) Pub. No.: US 2019/0229055 A1
(43) Pub. Date: Jul. 25, 2019

(54) FAN-OUT SENSOR PACKAGE

(71) Applicant: SAMSUNG ELECTRO-MECHANICS CO., LTD., Suwon-si (KR)

(72) Inventors: Won Wook SO, Suwon-si (KR); Jin Seon PARK, Suwon-si (KR); Young Sik HUR, Suwon-si (KR); Yong Ho BAEK, Suwon-si (KR)

(21) Appl. No.: 16/107,727

(22) Filed: Aug. 21, 2018

(30) Foreign Application Priority Data
Jan. 24, 2018 (KR) 10-2018-0008711

(51) Int. Cl. H01L 23/522; H01L 23/00; H01L 21/56

(52) U.S. Cl. CPC H01L 23/5226; H01L 24/09; H01L 23/3128; H01L 24/17; H01L 24/49; H01L 21/56

(57) ABSTRACT

A fan-out sensor package includes: a first semiconductor chip module including a first connection member having a first through-hole and a first wiring layer, a first semiconductor chip disposed in the first through-hole and having an active surface on which a sensing region and first connection pads are disposed, and an encapsulant encapsulating at least portions of the first connection member and the first semiconductor chip and filling at least portions of the first through-hole; a redistribution module having a second through-hole exposing at least a portion of the sensing region and including a redistribution layer; and electrical connection structures electrically connecting the first wiring layer and the first connection pads to the redistribution layer.

### CROSS-REFERENCE TO RELATED APPLICATION(S)

This application claims benefit of priority to Korean Patent Application No. 10-2018-0008711 filed on Jan. 24, 2018 in the Korean Intellectual Property Office, the disclosure of which is incorporated herein by reference in its entirety.

### TECHNICAL FIELD

The present disclosure relates to a fan-out sensor package.

### BACKGROUND

In sensor products in which a sensing region needs to be externally opened or which may be opened to the air, there are many limitations at the time of packing a die. Therefore, a size, a thickness, and the like, of an external package, are increased.

Recently, in smartphones or Internet of Things (IoT) products, sizes, thicknesses, and the like, of many components used in the products have been reduced in order to reduce a mounting area and a thickness, but the sensor products in which the sensing region is opened have a limitation in reducing a size of a package.

Inmost sensor dies in which electrical circuits, signal pads, a sensing region exists on the same surface, a wire bonding manner has been used in order to connect signals to an input/output (I/O) of an external package, and an air gap of a predetermined size has been required in the vicinity of the sensing region.

Therefore, a sensor die and an application specific integrated circuit (ASIC) die may be attached to a substrate or a ceramic housing case, and signals are transmitted between a sensor and an ASIC through wire bonding, or signals are transmitted directly from a sensor to a substrate by wire bonding.

In addition, a metal can seal the substrate or the ceramic housing case in a state in which it is upwardly spaced apart from the substrate or the ceramic housing case by a predetermined space, and a hole is formed in the metal can or a printed circuit board (PCB) to manufacture a package communicating externally. Therefore, when the package is manufactured as described above, there is a limitation in reducing a height of a component and a size of the component may not be reduced.

### SUMMARY

An aspect of the present disclosure may provide a fan-out sensor package including a first semiconductor chip and capable of being implemented to have a compact size and a small thickness.

An aspect of the present disclosure may also provide a fan-out sensor package of which a manufacturing yield may be improved.

According to an aspect of the present disclosure, a fan-out sensor package may include: a first semiconductor chip module including a first connection member having a first through-hole and a first wiring layer, a first semiconductor chip disposed in the first through-hole and having an active surface on which a sensing region and first connection pads are disposed, and an encapsulant encapsulating at least portions of the first connection member and the first semiconductor chip and filling at least portions of the first through-hole; a redistribution module having a second through-hole exposing at least a portion of the sensing region and including a redistribution layer; and electrical connection structures electrically connecting the first wiring layer and the first connection pads to the redistribution layer.

The electrical connection structure may be made of a low melting point material including a solder.

A plurality of electrical connection structures may be spaced apart from each other.

The sensing region of the first semiconductor chip may be disposed below the second through-hole of the redistribution module.

The first connection member may include: a first insulating layer in which the first through-hole is formed; the first wiring layer disposed on at least one of an upper surface and a lower surface of the first insulating layer; and first vias connected to the first wiring layers to each other.

The first connection member may further include a first metal layer disposed on at least inner walls of the first through-hole.

The electrical connection structure may be made of a conductive film.

The first semiconductor chip module may further include a passive element electrically connected to the first wiring layer and disposed in an insertion groove of the first insulating layer.

The first semiconductor chip may have the active surface having the sensing region disposed below the first through-hole and the first connection pads disposed in the vicinity of the sensing region.

The redistribution module may include a mesh portion disposed in the second through-hole.

The first connection member may further includes a third through-hole, and the first semiconductor chip module may further include a second semiconductor chip disposed in the third through-hole.

The redistribution module may completely cover an active surface of the second semiconductor chip.

The redistribution module may cover the first connection pads.

According to another aspect of the present disclosure, a fan-out sensor package may include: a first semiconductor chip package; and a second semiconductor chip package, wherein the first semiconductor chip package includes: a first semiconductor chip module including a first connection member having a first through-hole and a first wiring layer, a first semiconductor chip disposed in the first through-hole and having an active surface on which a sensing region and first connection pads are disposed, and a first encapsulant encapsulating at least portions of the first connection member and the first semiconductor chip and filling at least portions of the first through-hole; a first redistribution module having a second through-hole exposing at least a portion of the sensing region and including a first redistribution layer; and first electrical connection structures electrically connecting each of the first wiring layer and the first connection pads to the first redistribution layer, and wherein the second semiconductor chip package includes: a second semiconductor chip module including a second connection member having a third through-hole and a second wiring layer, a second semiconductor chip disposed in the third through-hole and having second connection pads disposed on an upper surface thereof, and a second encapsulant encapsulating at least portions of the second connection member and the second semiconductor chip and filling at least portions of the third through-hole; a second redistribution module including a second redistribution layer; and second electrical connection structures electrically connecting the second wiring layer and the second connection pads to the second redistribution layer.

Each of the first and second electrical connection structures may be made of a low melting point material including a solder.

The fan-out sensor package may further include third electrical connection structures electrically connecting the first semiconductor chip package and the second semiconductor chip package to each other.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a ball grid array (BGA) substrate and is ultimately mounted on a mainboard of an electronic device;

FIG. 6 is a schematic cross-sectional view illustrating a case in which a fan-in semiconductor package is embedded in a BGA substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating a fan-out sensor package according to a first exemplary embodiment in the present disclosure;

FIG. 10 is a plan view illustrating a fan-out sensor package according to a first exemplary embodiment in the present disclosure;

FIGS. 11 through 21 are views for describing a method of manufacturing a fan-out sensor package according to a first exemplary embodiment in the present disclosure;

FIG. 22 is a view for describing a method of manufacturing a fan-out sensor package according to a second exemplary embodiment in the present disclosure;

FIGS. 23 and 24 are views for describing a method of manufacturing a fan-out sensor package according to a third exemplary embodiment in the present disclosure;

FIG. 25 is a schematic cross-sectional view illustrating a fan-out sensor package according to a second exemplary embodiment in the present disclosure;

FIG. 26 is a schematic cross-sectional view illustrating a fan-out sensor package according to a third exemplary embodiment in the present disclosure;

FIG. 27 is a schematic plan view illustrating the fan-out sensor package according to a third exemplary embodiment in the present disclosure;

FIG. 28 is a schematic cross-sectional view illustrating a fan-out sensor package according to a fourth exemplary embodiment in the present disclosure; and

FIG. 29 is a schematic cross-sectional view illustrating a fan-out sensor package according to a fifth exemplary embodiment in the present disclosure.

### DETAILED DESCRIPTION

Hereinafter, exemplary embodiments of the present disclosure will now be described in detail with reference to the accompanying drawings.

Electronic Device

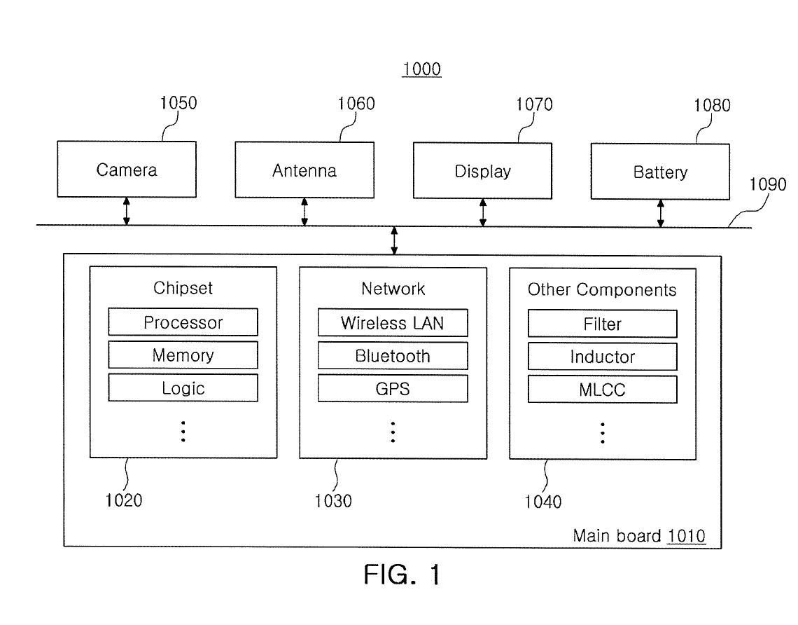

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

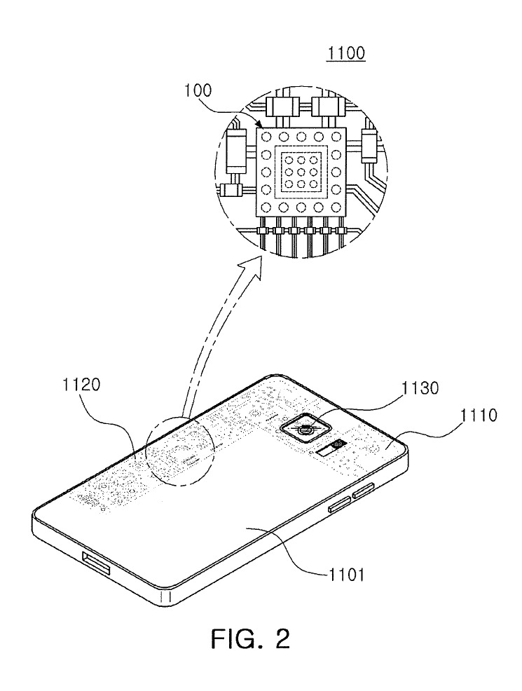

FIG. 2 is a schematic perspective view illustrating an example of an electronic device.

Referring to FIG. 2, an electronic device may be, for example, a smartphone 1100. A mainboard 1110 may be accommodated in a body 1101 of the smartphone 1100, and various electronic components 1120 such as a semiconductor package 1121 may be physically or electrically connected to the mainboard 1110. In addition, other components that may or may not be physically or electrically connected to the mainboard 1110, such as the camera module 1130, may be accommodated in the body 1101. The camera module 1130 may include an image sensor package, and a fan-out sensor package according to the present disclosure may be used in the smartphone. Meanwhile, the electronic device in which the fan-out sensor package according to the present disclosure is used is not limited to the smartphone 1100. That is, the fan-out sensor package according to the present disclosure may also be used in other electronic devices.

Semiconductor Package

A fan-out sensor package according to the present disclosure may be manufactured using technology of a semiconductor package. Generally, numerous fine electrical circuits are integrated in a semiconductor. However, the semiconductor may not serve as a finished semiconductor product in itself, and may be damaged due to external physical or chemical impacts. Therefore, the semiconductor itself may not be used, but may be packaged and used in an electronic device, or the like, in a packaged state.

Here, semiconductor packaging is required due to the existence of a difference in a circuit width between the semiconductor and a mainboard of the electronic device in terms of electrical connections. In detail, a size of connection pads of the semiconductor and an interval between the connection pads of the semiconductor are very fine, but a size of component mounting pads of the mainboard and an interval between the component mounting pads of the mainboard are significantly larger than those of the semiconductor. Therefore, it may be difficult to directly mount the semiconductor on the mainboard, and packaging technology for buffering a difference in a circuit width between the semiconductor and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

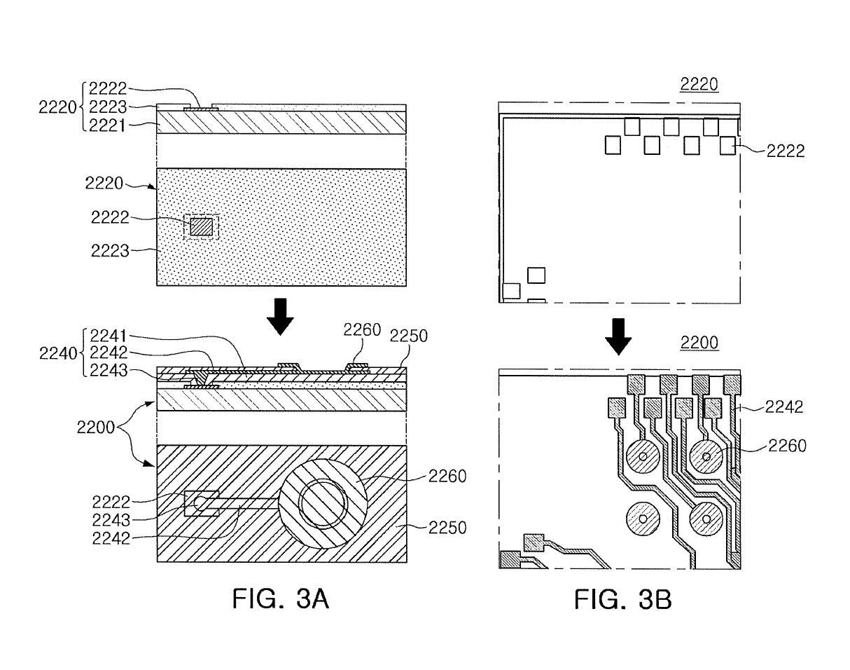

FIGS. 3A and 3B are schematic cross-sectional views illustrating states of a fan-in semiconductor package before and after being packaged.

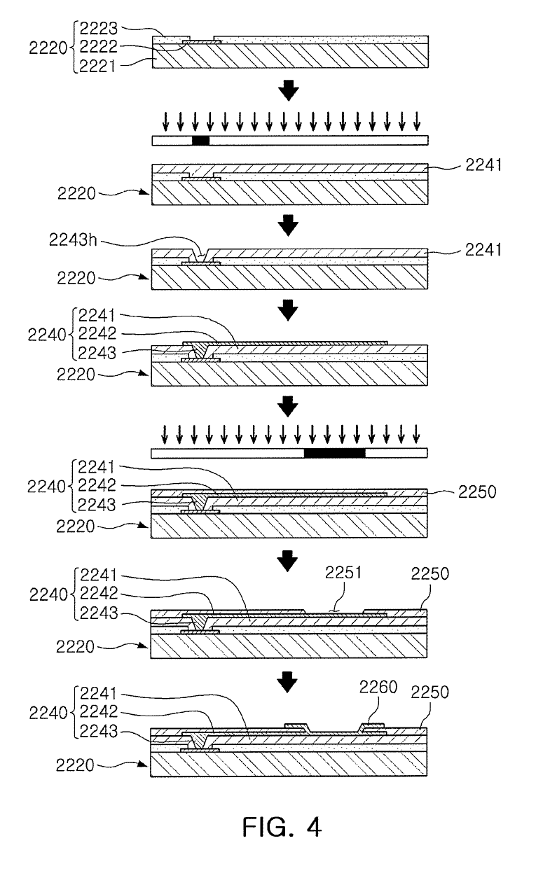

FIG. 4 is schematic cross-sectional views illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor are disposed inside the semiconductor, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor in the fan-in semiconductor package, the fan-in semiconductor package has significant spatial limitations. Therefore, it is difficult to apply this structure to a semiconductor having a large number of I/O terminals or a semiconductor having a compact size. In addition, due to the disadvantage described above, the fan-in semiconductor package may not be directly mounted and used on the mainboard of the electronic device. The reason is that even in the case in which a size of the I/O terminals of the semiconductor and an interval between the I/O terminals of the semiconductor are increased by a redistribution process, the size of the I/O terminals of the semiconductor and the interval between the I/O terminals of the semiconductor may not be sufficient to directly mount the fan-in semiconductor package on the mainboard of the electronic device.

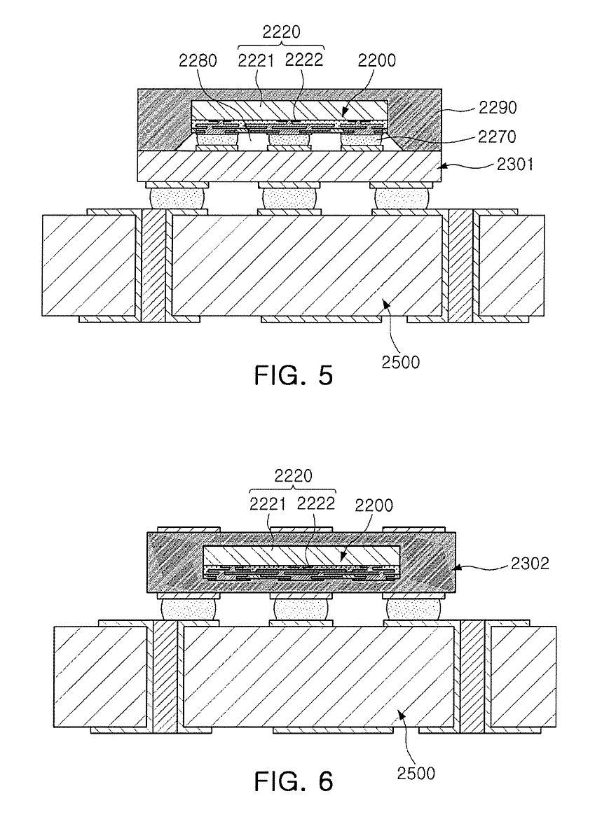

FIG. 5 is a schematic cross-sectional view illustrating a case in which a fan-in semiconductor package is mounted on a ball grid array (BGA) substrate and is ultimately mounted on a mainboard of an electronic device.

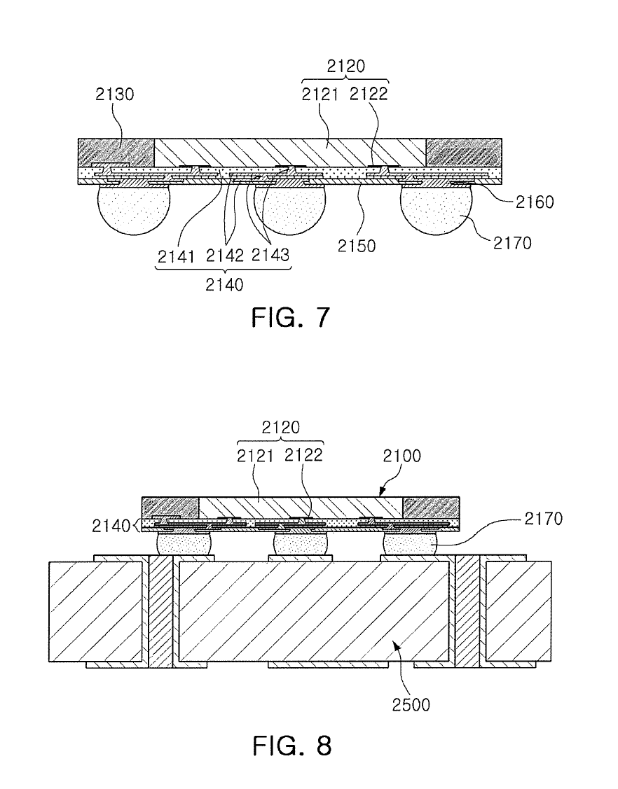

FIG. 6 is a schematic cross-sectional view illustrating a case in which a fan-in semiconductor package is embedded in a BGA substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

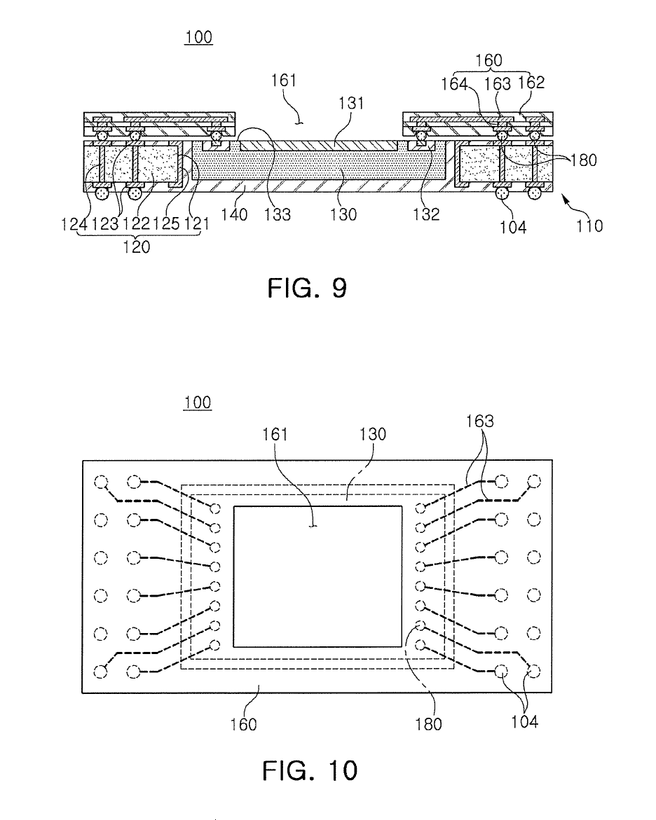

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2150, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor are redistributed and disposed outwardly of the semiconductor through the connection member formed on the semiconductor. As described above, in the fan-in semiconductor package, all I/O terminals of the semiconductor need to be disposed inside the semiconductor. Therefore, when a size of the semiconductor is decreased, a size and a pitch of balls need to be decreased, such that a standardized ball layout may not be used in the fan-in semiconductor package. On the other hand, the fan-out semiconductor package has the form in which the I/O terminals of the semiconductor are redistributed and disposed outwardly of the semiconductor through the connection member formed on the semiconductor as described above. Therefore, even in the case in which a size of the semiconductor is decreased, a standardized ball layout may be used in the fan-out semiconductor package as it is, such that the fan-out semiconductor package may be mounted on the mainboard of the electronic device without using a separate BGA substrate, as described below.

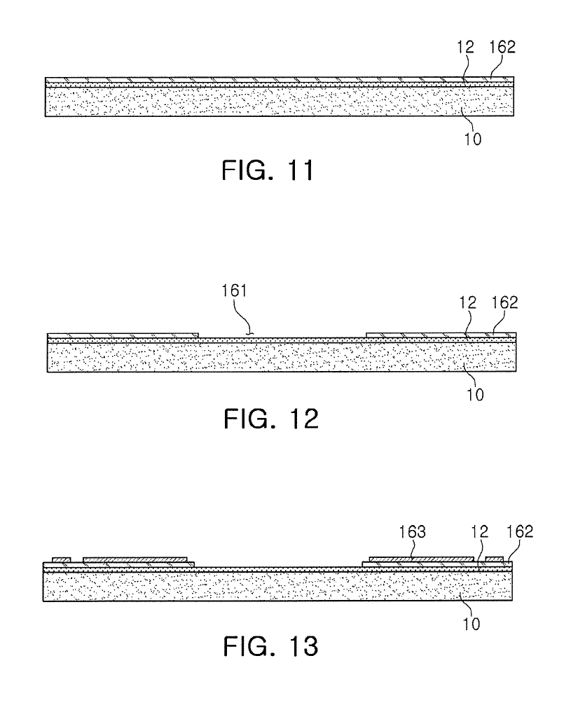

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor on the mainboard of the electronic device, or the like, as described above, and protecting the semiconductor from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

A fan-out sensor package according to the present disclosure may be manufactured using the fan-out semiconductor package technology described above. A fan-out sensor package according to the present disclosure will hereinafter be described with reference to the drawings.

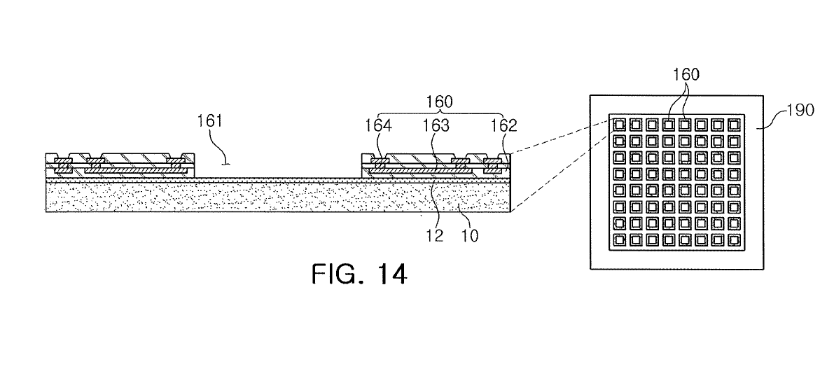

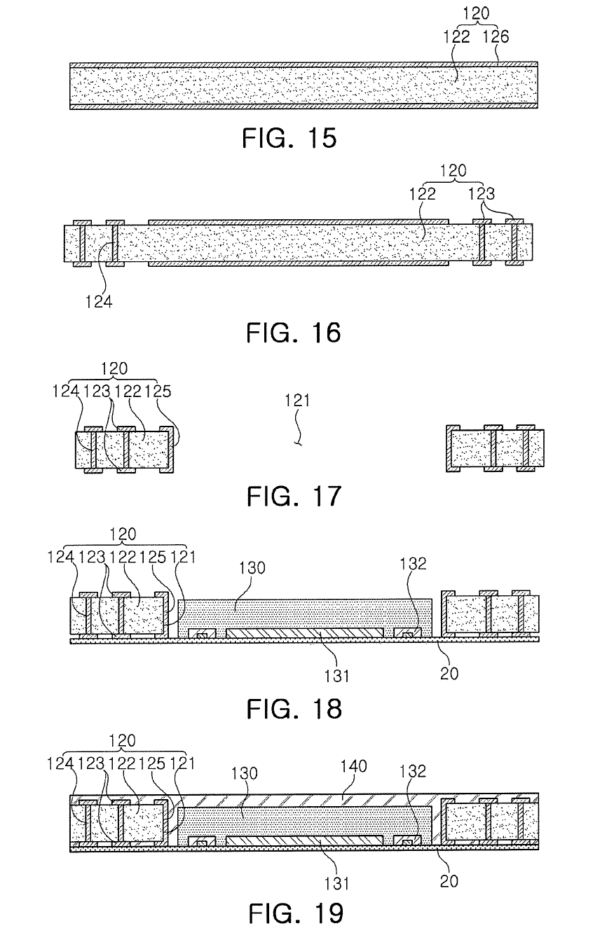

FIG. 9 is a schematic cross-sectional view illustrating a fan-out sensor package according to a first exemplary embodiment in the present disclosure, and FIG. 10 is a plan view illustrating a fan-out sensor package according to a first exemplary embodiment in the present disclosure.

Referring to FIGS. 9 and 10, a fan-out sensor package 100 according to a first exemplary embodiment in the present disclosure may include a first semiconductor chip module 110 and a redistribution module 160 as an example.

Meanwhile, the first semiconductor chip module 110 and the redistribution module 160 may be separately manufactured and be then coupled to each other.

The first semiconductor chip module 110 may include a first connection member 120, a first semiconductor chip 130, and an encapsulant 140 as an example.

A first through-hole 121 in which the first semiconductor chip 130 is disposed may be formed in the first connection member 120. As an example, the first connection member 120 may be provided to support the fan-out sensor package 100, and may maintain rigidity and secure uniformity of a thickness.

In the present exemplary embodiment, side surfaces of the first semiconductor chip 130 may be surrounded by the first connection member 120. However, such a form is only an example and may be variously modified to have other forms, and the first connection member 120 may perform another function depending on such a form.

Meanwhile, a first insulating layer 122 of the first connection member 120 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, Ajinomoto Build-up Film (ABF), FR-4, a Bismaleimide Triazine (BT) resin, or the like, but is not limited thereto. A metal having excellent rigidity and thermal conductivity may be disposed in the first insulating layer 122. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the first insulating layer 122. In addition, the first insulating layer 122 may serve as a support member.

A first wiring layer 123 of the first connection member 120 may be disposed on at least one of an upper surface and a lower surface of the first insulating layer 122. Meanwhile, a plurality of first wiring layers 123 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first wiring layers 123 may be formed by any known method such as electrolytic copper plating, electroless copper plating, or the like. In more detail, the first wiring layers 123 may be formed using a method such as chemical vapor deposition (CVD), physical vapor deposition (PVD), sputtering, a subtractive process, an additive process, a semi-additive process (SAP), a modified semi-additive process (MSAP), or the like, but is not limited thereto.

Meanwhile, portions of the first wiring layer 123 may be externally exposed.

In addition, first vias 124 of the first connection member 120 may penetrate through the first insulating layer 122 to connect the first wiring layers 123 to each other. In addition, the first vias 124 may be formed of the same material as that of the first wiring layer 123. As an example, a plurality of first vias 124 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first vias 124 may be formed by any known method such as electrolytic copper plating, electroless copper plating, or the like. In more detail, the first vias 124 may be formed using a method such as CVD, PVD, sputtering, a subtractive process, an additive process, an SAP, an MSAP, or the like, but are not limited thereto.

Meanwhile, a first metal layer 125 of the first connection member 120 may be disposed on at least inner walls of the first through-hole 121. In addition, the first metal layer 125 may extend from the inner walls of the first through-hole 121 and may also be disposed on the upper surface and the lower upper of the first insulating layer 122.

The first metal layer 125 may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof, similar to the first wiring layers 123 and the first vias 124. The first metal layer 125 may be formed by any known method such as electrolytic copper plating, electroless copper plating, or the like. In more detail, the first plating layer 125 may be formed using a method such as CVD, PVD, sputtering, a subtractive process, an additive process, an SAP, an MSAP, or the like, but is not limited thereto.

The first semiconductor chip 130 may have an active surface 133 having a sensing region 131 disposed at a central portion thereof and first connection pads 132 disposed in the vicinity of the sensing region 131 and provided for electrical connection to the redistribution module 160.

As an example, the first semiconductor chip 130 may be a complementary metal oxide semiconductor (CMOS) image sensor (CIS), but is not limited thereto. The first semiconductor chip 130 may be formed on the basis of an active wafer. In this case, a base material of a body of the first semiconductor chip may be silicon (Si), germanium (Ge), gallium arsenide (GaAs), or the like. Various circuits may be formed on the body. The first connection pads 132 may electrically connect the first semiconductor chip 130 to other components, and a conductive material such as aluminum (Al), or the like, may be used as a material of each of the first connection pads 132.

The first semiconductor chip 130 may be any one of sensor products having a structure in which a sensing region is exposed to the air among sensors used in electronic devices, mobile devices, smartphones, IoT products, or a sensor network device, that is, a chemical sensor detecting chemical substances, particles, or the like, in the air, an image sensor receiving and recognizing light, an optical sensor such as an infrared (IR) sensor or an ultraviolet (UV) sensor, a MIC sensor recognizing a user's voice, and a fingerprint sensor analyzing a fingerprint, as an example.

The encapsulant 140 may encapsulate the first connection member 120 and the first semiconductor chip 130. As an example, the encapsulant 140 may serve to protect the first semiconductor chip 130. An encapsulation form of the encapsulant 140 is not particularly limited, but may be a form in which the encapsulant 140 surrounds at least portions of the first semiconductor chip 130. For example, the encapsulant 140 may cover at least portions of the first connection member 120 and the first semiconductor chip 130. Certain materials of the encapsulant 140 are not particularly limited. For example, an insulating material may be used as the certain materials of the encapsulant 140. In this case, the insulating material may be a thermosetting resin such as an epoxy resin, a thermoplastic resin such as polyimide, a resin having a reinforcing material such as an inorganic filler impregnated in the thermosetting resin and the thermoplastic resin, for example, ABF, FR-4, BT, a PID resin, or the like. In addition, any known molding material such as an EMC, or the like, may also be used. Alternatively, a resin in which a thermosetting resin or a thermoplastic resin is impregnated together with an inorganic filler in a core material such as a glass fiber (or a glass cloth or a glass fabric) may also be used as the insulating material.

Meanwhile, the first semiconductor chip module 110 may be manufactured in a panel level package (PLP) manner.

The redistribution module 160 may be disposed on one surface of the first semiconductor chip module 110. As an example, the redistribution module 160 may include insulating layers 162 in which a second through-hole 161 is formed, redistribution layers 163 having portions exposed from the insulating layers 162 and forming at least one layer, and vias 164 connecting the redistribution layers 163 to each other.

In addition, a material of each of the insulating layers 162 may be an insulating material. In this case, a photosensitive insulating material such as a PID resin may also be used as the insulating material. That is, each of the insulating layers 162 may be a photosensitive insulating layer. When the insulating layer 162 has photosensitive properties, the insulating layer 162 may be formed to have a smaller thickness, and a fine pitch of the via 164 may be achieved more easily. Each of the insulating layers 162 may be a photosensitive insulating layer including an insulating resin and an inorganic filler. When the insulating layers 162 are multiple layers, materials of the insulating layers 162 may be the same as each other, and may also be different from each other, if necessary. When the insulating layers 162 are the multiple layers, the insulating layers 162 may be integrated with each other depending on a process, such that a boundary therebetween may also not be apparent.

The redistribution layers 163 may serve to substantially redistribute the first connection pads 132 of the first semiconductor chip 130. A material of each of the redistribution layers 163 may be a conductive material such as copper (Cu), aluminum (Al), silver (Ag), tin (Sn), gold (Au), nickel (Ni), lead (Pb), titanium (Ti), or alloys thereof. The redistribution layers 163 may perform various functions depending on designs of corresponding layers. For example, the redistribution layers 163 may include ground patterns, power patterns, signal patterns, and the like. Here, the signal patterns may include various signals except for the ground patterns, the power patterns, and the like, such as data signals, and the like. In addition, the redistribution layers 163 may include various pad patterns, and the like.

In addition, the redistribution layers 163, which are a plurality of layers, may be electrically connected to each other through the vias 164.

Meanwhile, the first semiconductor chip module 110 and the redistribution module 160 may be mechanically coupled to each other by electrical connection structures 180, and the redistribution layer 163 may be electrically connected to at least one of the first wiring layer 123 and the first connection pads 132 by the electrical connection structures 180.

Each of the electrical connection structures 180 may be formed of a conductive material, for example, a solder, or the like. However, this is only an example, and a material of each of the electrical connection structures 180 is not particularly limited thereto. The electrical connection structures 180 may be formed as a multilayer or single layer structure. When the electrical connection structures 180 are formed as a multilayer structure, the electrical connection structures 180 may include a copper (Cu) pillar and a solder. When the electrical connection structures 180 are formed as a single layer structure, the electrical connection structures 180 may include a tin-silver solder or copper (Cu). However, this is only an example, and the electrical connection structures 180 are not limited thereto.

The number, an interval, a disposition form, and the like, of electrical connection structures 180 are not particularly limited, but may be sufficiently modified depending on design particulars by those skilled in the art. For example, the electrical connection structures 180 may be provided in an amount of several tens to several thousands according to the number of first connection pads 132 of the first semiconductor chip 130, or may be provided in an amount of several tens to several thousands or more or several tens to several thousands or less. The electrical connection structures 180 may be solder balls and at least fill openings of the lowermost insulating layer 162 exposing portions of the redistribution layer 163, such that the electrical connection structures 180 may connect the exposed portions of the redistribution layer 163 to the first wiring layer 123 disposed on the upper surface of the first insulating layer 122. Alternatively, when the electrical connection structures 180 are solder balls, the electrical connection structures 180 may cover side surfaces of the redistribution layer 163 and/or the first wiring layer 123 extending onto one surface of a passivation layer (not illustrated), and connection reliability may be more excellent.

At least one of the electrical connection structures 180 may be disposed in a fan-out region. The fan-out region refers to a region except for the region in which the first semiconductor chip 130 is disposed. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be manufactured to have a small thickness, and may have price competitiveness.

Meanwhile, solders 104 for connection to a mainboard (not illustrated) may be formed on the first wiring layer 123 of the first connection member 120 externally exposed from the encapsulant 140.

As described above, the fan-out sensor package 100 may be manufactured by separating manufacturing the first semiconductor chip module 110 and the redistribution module 160 and then coupling the first semiconductor chip module 110 and the redistribution module 160 to each other, and a manufacturing yield of the fan-out sensor package 100 may thus be improved.

Further, the fan-out sensor package 100 may be implemented to have a compact size and a small thickness.

A method of manufacturing a fan-out sensor package according to a first exemplary embodiment in the present disclosure will hereinafter be described with reference to the drawings.

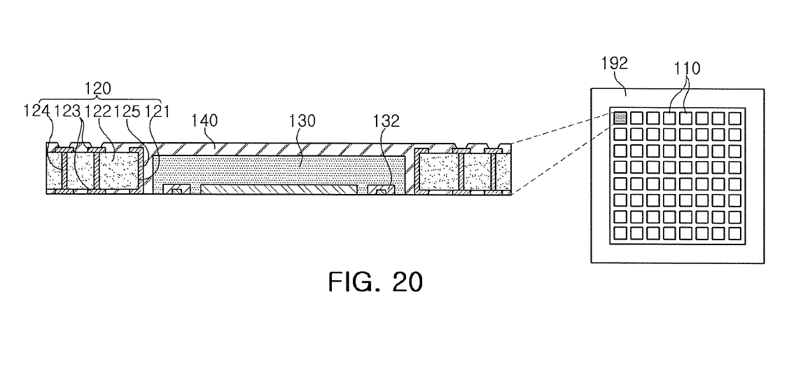

FIGS. 11 through 21 are views for describing a method of manufacturing a fan-out sensor package according to a first exemplary embodiment in the present disclosure.

First, as illustrated in FIG. 11, an insulating layer 162 may be formed on a carrier 10 on which an adhesive layer 12 is formed. In this case, the insulating layer 162 may be formed of, for example, a photoimagable dielectric (PID) material on which an exposure process is used or an organic material on which a laser drill may be used.

Then, as illustrated in FIG. 12, the second through-hole 161 may be formed by removing a central portion of the insulating layer 162. That is, the insulating layer 162 may be removed by a region corresponding to the sensing region 131 (see FIG. 9) of the first semiconductor chip 130 (see FIG. 9). The insulating layer 162 may be removed by an exposure process or a drill process depending on a material.

Then, as illustrated in FIG. 13, the redistribution layer 163 may be formed on the insulating layer 162.

Then, as illustrated in FIG. 14, a plurality of insulating layers 162 and redistribution layers 163 may be formed. Meanwhile, portions of the redistribution layers 163 may be formed to be externally exposed from the insulating layers 162, and the redistribution layers 163 may be connected to each other through the vias 164. A case in which the redistribution module 160 includes three insulating layers 162 and two redistribution layers 163 is described by way of example in the present exemplary embodiment. However, the redistribution module 160 is not limited thereto, but may be variously modified.

The redistribution module 160 may be formed on a redistribution module panel 190.

In addition, as illustrated in FIG. 15, the first connection member 120 including the first insulating layer 122 and conductor layers 126 may be prepared.

Then, as illustrated in FIG. 16, the first wiring layers 123 disposed on the upper surface and the lower surface of the first insulating layer 122 may be connected to each other by forming the vias 124 while removing portions of the conductor layers 126.

Then, as illustrated in FIG. 17, the first through-hole 121 may be formed in a central portion of the first connection member 120, and the first metal layer 125 disposed on the inner walls of the first through-hole 121 of the first insulating layer 122 may be formed. The first metal layer 125 may extend to the upper surface and the lower surface of the first insulating layer 122.

Then, as illustrated in FIG. 18, an adhesive tape 20 may be adhered to a lower surface of the first connection member 120, and the first semiconductor chip 130 may be mounted on the adhesive tape 20 to be disposed in the first through-hole 121.

Then, as illustrated in FIG. 19, the first connection member 120 and the first semiconductor chip 130 may be encapsulated through the encapsulant 140. Then, as illustrated in FIG. 20, the adhesive tape 20 may be removed, and portions of the encapsulant 140 may be removed so that the first wiring layer 123 is externally exposed from the first insulating layer 122. A plurality of first semiconductor chip modules 110 may be formed on a first semiconductor chip module panel 192.

Then, as illustrated in FIG. 21, the redistribution module panel 190 on which a plurality of redistribution modules 160 are formed and the first semiconductor chip module panel 192 on which a plurality of first semiconductor chip modules 110 are formed may be mechanically coupled to each other while being electrically connected to each other through the electrical connection structures 180.

Then, the carrier 10 attached to a lower surface of the redistribution modules 160 may be removed. In addition, the first semiconductor chip modules 110 and the redistribution modules 160 coupled to each other may be diced in a single unit to manufacture the fan-out sensor packages 100.

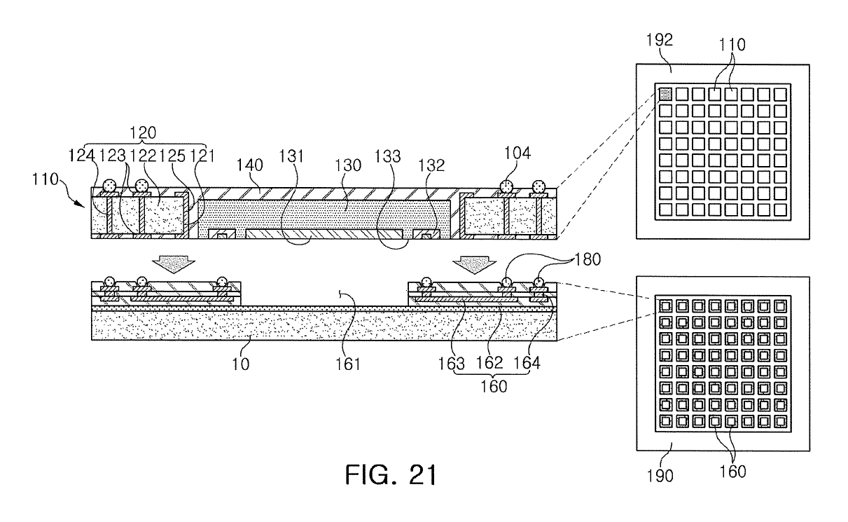

FIG. 22 is a view for describing a method of manufacturing a fan-out sensor package according to a second exemplary embodiment in the present disclosure.

Referring to FIG. 22, a plurality of unit first semiconductor chip modules 110 may be mounted on the redistribution module panel 190, and the first semiconductor chip modules 110 and the redistribution modules 160 coupled to each other may be diced in a single unit to manufacture the fan-out sensor packages 100.

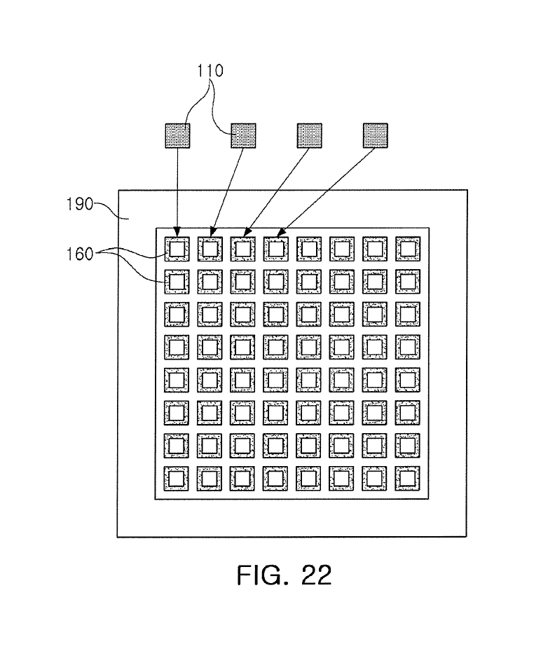

FIGS. 23 and 24 are views for describing a method of manufacturing a fan-out sensor package according to a third exemplary embodiment in the present disclosure.

Referring to FIG. 23, a conductive film 194 may be inserted between the redistribution module panel 190 on which the plurality of redistribution modules 160 are formed and the first semiconductor chip module panel 192 on which the plurality of first semiconductor chip modules 110 are formed, and the first semiconductor chip modules 110 and the redistribution modules 160 may be electrically connected to each other through the conductive film 194.

Then, as illustrated in FIG. 24, the carrier 10 may be removed, and the first semiconductor chip modules 110 and the redistribution modules 160 coupled to each other may be diced in a single unit to manufacture the fan-out sensor packages 100.

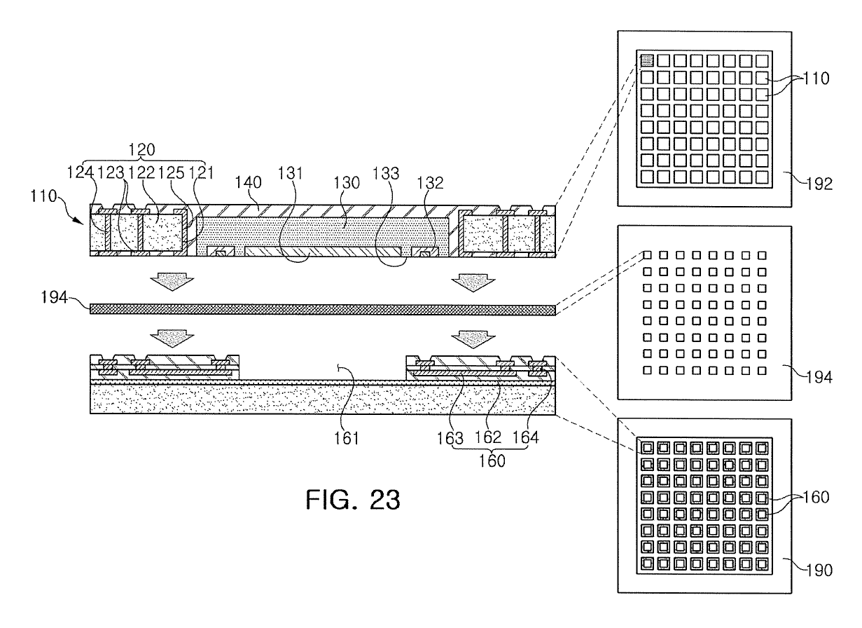

FIG. 25 is a schematic cross-sectional view illustrating a fan-out sensor package according to a second exemplary embodiment in the present disclosure.

Referring to FIG. 25, a fan-out sensor package 200 according to a second exemplary embodiment in the present disclosure may include a first semiconductor chip module 210 and a redistribution module 160 as an example.

Meanwhile, the redistribution module 160 is substantially the same as the redistribution module described above. Therefore, a detailed description for the redistribution module is omitted and is replaced by the abovementioned description.

The first semiconductor chip module 210 may include a first connection member 220, a first semiconductor chip 230, an encapsulant 240, and a passive element 250 as an example.

A first through-hole 221a in which the first semiconductor chip 230 is disposed and an insertion groove 221b in which the passive element 250 is disposed may be formed in the first connection member 220. As an example, the first connection member 220 may be provided to support the fan-out sensor package 200, and may maintain rigidity and secure uniformity of a thickness.

In the present exemplary embodiment, side surfaces of the first semiconductor chip 230 and the passive element 250 may be surrounded by the first connection member 220. However, such a form is only an example and may be variously modified to have other forms, and the first connection member 220 may perform another function depending on such a form.

Meanwhile, a first insulating layer 222 of the first connection member 220 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, ABF, FR-4, a BT resin, or the like, but is not limited thereto. A metal having excellent rigidity and thermal conductivity may be disposed in the first insulating layer 222. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the first insulating layer 222. In addition, the first insulating layer 222 may serve as a support member.

A first wiring layer 223 of the first connection member 220 may be disposed on at least one of an upper surface and a lower surface of the first insulating layer 222. Meanwhile, a plurality of first wiring layers 223 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first wiring layers 223 may be formed by any known method such as electrolytic copper plating, electroless copper plating, or the like. In more detail, the first wiring layers 223 may be formed using a method such as CVD, PVD, sputtering, a subtractive process, an additive process, an SAP, an MSAP, or the like, but are not limited thereto.

Meanwhile, portions of the first wiring layer 223 may be externally exposed.

In addition, first vias 224 of the first connection member 220 may penetrate through the first insulating layer 222 to connect the first wiring layers 223 to each other. In addition, the first vias 224 may be formed of the same material as that of the first wiring layer 223. As an example, a plurality of first vias 224 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first vias 224 may be formed by any known method such as electrolytic copper plating, electroless copper plating, or the like. In more detail, the first vias 224 may be formed using a method such as CVD, PVD, sputtering, a subtractive process, an additive process, an SAP, an MSAP, or the like, but are not limited thereto.

Meanwhile, a first metal layer 225 of the first connection member 220 may be disposed on at least inner walls of the first through-hole 221a. In addition, the first metal layer 225 may extend from the inner walls of the first through-hole 221a and may also be disposed on the upper surface and the lower upper of the first insulating layer 222.

The first metal layer 225 may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof, similar to the first wiring layers 223 and the first vias 224. The first metal layer 225 may be formed by any known method such as electrolytic copper plating, electroless copper plating, or the like. In more detail, the first metal layer 225 may be formed using a method such as CVD, PVD, sputtering, a subtractive process, an additive process, an SAP, an MSAP, or the like, but is not limited thereto.

The first semiconductor chip 230 may have an active surface 233 having a sensing region 231 disposed at a central portion thereof and first connection pads 232 disposed in the vicinity of the sensing region 231 and provided for electrical connection to the redistribution module 160.

As an example, the first semiconductor chip 230 may be a CIS, but is not limited thereto. The first semiconductor chip 230 may be formed on the basis of an active wafer. In this case, a base material of a body of the first semiconductor chip may be silicon (Si), germanium (Ge), gallium arsenide (GaAs), or the like. Various circuits may be formed on the body. The first connection pads 232 may electrically connect the first semiconductor chip 230 to other components, and a conductive material such as aluminum (Al), or the like, may be used as a material of each of the first connection pads 232.

The first semiconductor chip 230 may be any one of sensor products having a structure in which a sensing region is exposed to the air among sensors used in electronic devices, mobile devices, smartphones, IoT products, or a sensor network device, that is, a chemical sensor detecting chemical substances, particles, or the like, in the air, an image sensor receiving and recognizing light, an optical sensor such as an IR sensor or a UV sensor, a MIC sensor recognizing a user's voice, and a fingerprint sensor analyzing a fingerprint, as an example.

The encapsulant 240 may encapsulate the first connection member 220, the first semiconductor chip 230, and the passive element 250. As an example, the encapsulant 240 may serve to protect the first semiconductor chip 230. An encapsulation form of the encapsulant 240 is not particularly limited, but may be a form in which the encapsulant 240 surrounds at least portions of the first semiconductor chip 230. For example, the encapsulant 240 may cover at least portions of the first connection member 220 and the first semiconductor chip 230. Certain materials of the encapsulant 240 are not particularly limited. For example, an insulating material may be used as the certain materials of the encapsulant 240. In this case, the insulating material may be a thermosetting resin such as an epoxy resin, a thermoplastic resin such as polyimide, a resin having a reinforcing material such as an inorganic filler impregnated in the thermosetting resin and the thermoplastic resin, for example, ABF, FR-4, BT, a PID resin, or the like. In addition, any known molding material such as an EMC, or the like, may also be used. Alternatively, a resin in which a thermosetting resin or a thermoplastic resin is impregnated together with an inorganic filler in a core material such as a glass fiber (or a glass cloth or a glass fabric) may also be used as the insulating material.

Meanwhile, the first semiconductor chip module 210 may be manufactured in a PLP manner.

The passive element 250 may be disposed in the insertion groove 221b of the first connection member 220, and be connected to the first wiring layers 223 through the first vias 224. Therefore, a mounting area of the passive element 250 may be reduced, and performance of the first semiconductor chip 230 may be improved. That is, the passive element 250 may be embedded and disposed in the first connection member 220.

The passive element 250 may be any one of a resistor, a capacitor, an inductor, a trance, and a relay as an example, and may serve to consume energy, accumulate energy therein, or pass energy therethrough.

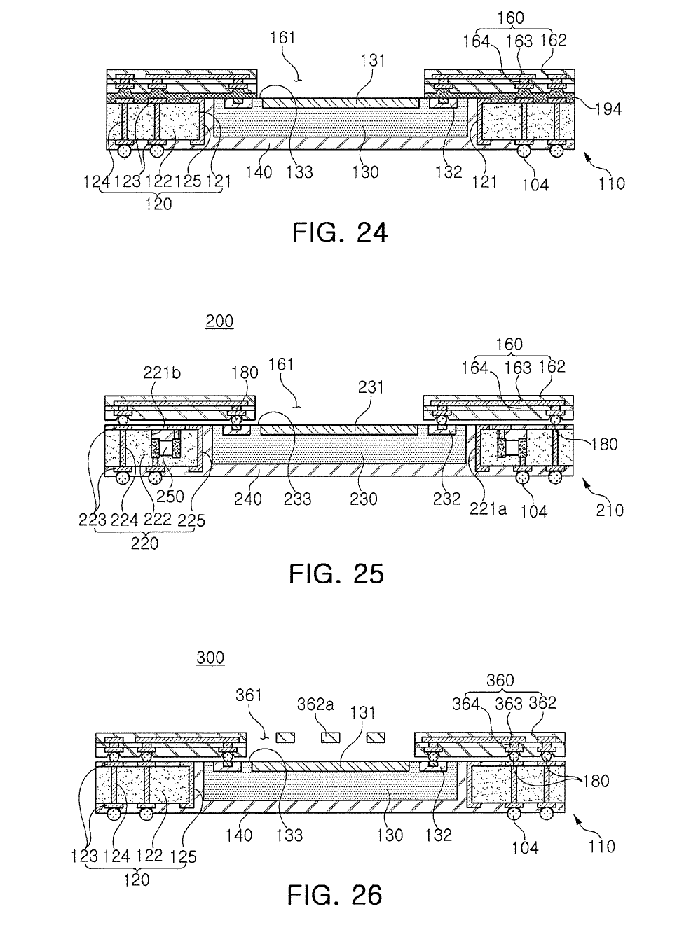

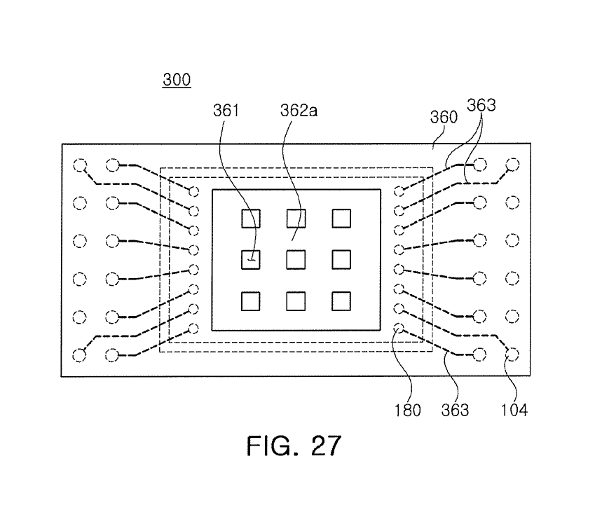

FIG. 26 is a schematic cross-sectional view illustrating a fan-out sensor package according to a third exemplary embodiment in the present disclosure, and FIG. 27 is a schematic plan view illustrating the fan-out sensor package according to a third exemplary embodiment in the present disclosure.

Referring to FIGS. 26 and 27, a fan-out sensor package 300 according to a third exemplary embodiment in the present disclosure may include a first semiconductor chip module 110 and a redistribution module 360 as an example.

Meanwhile, the first semiconductor chip module 110 is substantially the same as the first semiconductor chip module described above. Therefore, a detailed description for the first semiconductor chip module is omitted and is replaced by the abovementioned description.

The redistribution module 360 may be disposed on one surface of the first semiconductor chip module 110. As an example, the redistribution module 360 may include insulating layers 362 in which a second through-hole 361 is formed, redistribution layers 363 having portions exposed from the insulating layers 362 and forming at least one layer, and vias 364 connecting the redistribution layers 363 to each other.

In addition, a material of each of the insulating layers 362 may be an insulating material. In this case, a photosensitive insulating material such as a PID resin may also be used as the insulating material. That is, each of the insulating layers 362 may be a photosensitive insulating layer. When the insulating layer 362 has photosensitive properties, the insulating layer 362 may be formed to have a smaller thickness, and a fine pitch of the via 364 may be achieved more easily. Each of the insulating layers 362 may be a photosensitive insulating layer including an insulating resin and an inorganic filler. When the insulating layers 362 are multiple layers, materials of the insulating layers 362 may be the same as each other, and may also be different from each other, if necessary. When the insulating layers 362 are the multiple layers, the insulating layers 362 may be integrated with each other depending on a process, such that a boundary therebetween may also not be apparent.

Meanwhile, the insulating layer 362 may include a mesh portion 362a for preventing introduction of foreign materials onto an upper surface of the first semiconductor chip 130. The mesh portion 362a may be disposed above the sensing region 131 of the first semiconductor chip 130 as an example.

The redistribution layers 363 may serve to substantially redistribute the first connection pads 132 of the first semiconductor chip 130. A material of each of the redistribution layers 363 may be a conductive material such as copper (Cu), aluminum (Al), silver (Ag), tin (Sn), gold (Au), nickel (Ni), lead (Pb), titanium (Ti), or alloys thereof. The redistribution layers 363 may perform various functions depending on designs of corresponding layers. For example, the redistribution layers 363 may include ground patterns, power patterns, signal patterns, and the like. Here, the signal patterns may include various signals except for the ground patterns, the power patterns, and the like, such as data signals, and the like. In addition, the redistribution layers 363 may include various pad patterns, and the like.

In addition, the redistribution layers 363, which are a plurality of layers, may be electrically connected to each other through the vias 364.

Meanwhile, the first semiconductor chip module 110 and the redistribution module 360 may be mechanically coupled to each other by electrical connection structures 180, and the redistribution layer 363 may be electrically connected to at least one of the first wiring layer 123 and the first connection pads 132 by the electrical connection structures 180.

Each of the electrical connection structures 180 may be formed of a low melting point material such as a solder, or the like. However, this is only an example, and a material of each of the electrical connection structures 180 is not particularly limited thereto. The electrical connection structures 180 may be formed as a multilayer or single layer structure. When the electrical connection structures 180 are formed as a multilayer structure, the electrical connection structures 180 may include a copper (Cu) pillar and a solder. When the electrical connection structures 180 are formed as a single layer structure, the electrical connection structures 180 may include a tin-silver solder or copper (Cu). However, this is only an example, and the electrical connection structures 180 are not limited thereto.

The number, an interval, a disposition form, and the like, of electrical connection structures 180 are not particularly limited, but may be sufficiently modified depending on design particulars by those skilled in the art. For example, the electrical connection structures 180 may be provided in an amount of several tens to several thousands according to the number of first connection pads 132 of the first semiconductor chip 130, or may be provided in an amount of several tens to several thousands or more or several tens to several thousands or less. The electrical connection structures 180 may be solder balls and at least fill openings of the lowermost insulating layer 362 exposing portions of the redistribution layer 363, such that the electrical connection structures 180 may connect the exposed portions of the redistribution layer 363 to the first wiring layer 123 disposed on the upper surface of the first insulating layer 122. Alternatively, when the electrical connection structures 180 are solder balls, the electrical connection structures 180 may cover side surfaces of the redistribution layer 363 and/or the first wiring layer 123 extending onto one surface of a passivation layer (not illustrated), and connection reliability may be more excellent.

At least one of the electrical connection structures 180 may be disposed in a fan-out region. The fan-out region refers to a region except for the region in which the first semiconductor chip 130 is disposed. The fan-out package may have excellent reliability as compared to a fan-in package, may implement a plurality of input/output (I/O) terminals, and may facilitate a 3D interconnection. In addition, as compared to a BGA package, an LGA package, or the like, the fan-out package may be manufactured to have a small thickness, and may have price competitiveness.

Meanwhile, solders 104 for connection to a mainboard (not illustrated) may be formed on the first wiring layer 123 of the first connection member 120 externally exposed from the encapsulant 140.

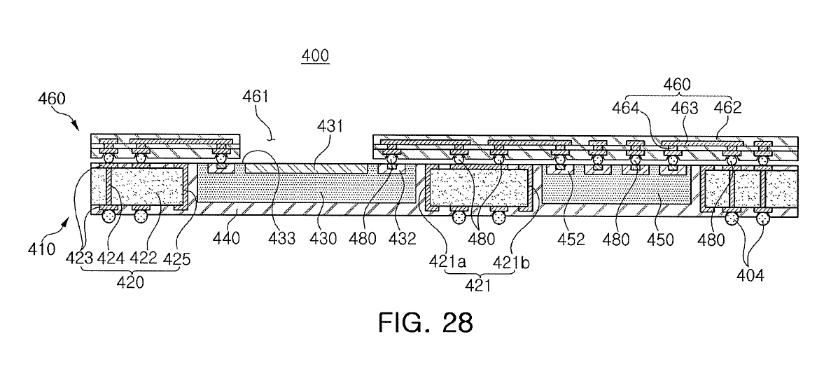

FIG. 28 is a schematic cross-sectional view illustrating a fan-out sensor package according to a fourth exemplary embodiment in the present disclosure.

Referring to FIG. 28, a fan-out sensor package 400 according to a fourth exemplary embodiment in the present disclosure may include a first semiconductor chip module 410 and a redistribution module 460 as an example.

Meanwhile, the first semiconductor chip module 410 and the redistribution module 460 may be separately manufactured and be then coupled to each other.

The first semiconductor chip module 410 may include a first connection member 420, a first semiconductor chip 430, an encapsulant 440, and a second semiconductor chip 450 as an example.

A plurality of first through-holes 421 may be formed in the first connection member 420. As an example, a 1-1-th through-hole 421a and a 1-2-th through-hole 421b disposed in parallel with each other in a horizontal direction may be formed in the first connection member 420. Meanwhile, the first semiconductor chip 430 may be disposed in the 1-1-th through-hole 421a, and the second semiconductor chip 450 may be disposed in the 1-2-th through-hole 421b. As an example, the first connection member 420 may be provided to support the fan-out sensor package 400, and may maintain rigidity and secure uniformity of a thickness.

In the present exemplary embodiment; side surfaces of the first semiconductor chip 430 and the second semiconductor chip 450 may be surrounded by the first connection member 420. However, such a form is only an example and may be variously modified to have other forms, and the first connection member 420 may perform another function depending on such a form.

Meanwhile, a first insulating layer 422 of the first connection member 420 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, ABF, FR-4, a BT resin, or the like, but is not limited thereto. A metal having excellent rigidity and thermal conductivity may be disposed in the first insulating layer 422. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the first insulating layer 422. In addition, the first insulating layer 422 may serve as a support member.

A first wiring layer 423 of the first connection member 420 may be disposed on at least one of an upper surface and a lower surface of the first insulating layer 422. Meanwhile, a plurality of first wiring layers 423 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first wiring layers 423 may be formed by any known method such as electrolytic copper plating, electroless copper plating, or the like. In more detail, the first wiring layers 423 may be formed using a method such as CVD, PVD, sputtering, a subtractive process, an additive process, an SAP, an MSAP, or the like, but are not limited thereto.

Meanwhile, portions of the first wiring layer 423 may be exposed externally of the encapsulant 440.

In addition, first vias 424 of the first connection member 420 may penetrate through the first insulating layer 422 to connect the first wiring layers 423 to each other. In addition, the first vias 424 may be formed of the same material as that of the first wiring layer 423. As an example, a plurality of first vias 424 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first vias 424 may be formed by any known method such as electrolytic copper plating, electroless copper plating, or the like. In more detail, the first vias 424 may be formed using a method such as CVD, PVD, sputtering, a subtractive process, an additive process, an SAP, an MSAP, or the like, but are not limited thereto.

Meanwhile, a first metal layer 425 of the first connection member 420 may be disposed on at least inner walls of the 1-1-th through-hole 421a and the 1-2-th through-hole 421b. In addition, the first metal layer 425 may extend from the inner walls of the 1-1-th through-hole 421a and the 1-2-th through-hole 421b and may also be disposed on the upper surface and the lower upper of the first insulating layer 422.

The first metal layer 425 may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof, similar to the first wiring layers 423 and the first vias 424. The first metal layer 425 may be formed by any known method such as electrolytic copper plating, electroless copper plating, or the like. In more detail, the first metal layer 425 may be formed using a method such as CVD, PVD, sputtering, a subtractive process, an additive process, an SAP, an MSAP, or the like, but is not limited thereto.

The first semiconductor chip 430 may have an active surface 433 having a sensing region 431 disposed at a central portion thereof and first connection pads 432 disposed in the vicinity of the sensing region 431 and provided for electrical connection to the redistribution module 460.

As an example, the first semiconductor chip 430 may be a CIS, but is not limited thereto. The first semiconductor chip 430 may be formed on the basis of an active wafer. In this case, a base material of a body of the first semiconductor chip may be silicon (Si), germanium (Ge), gallium arsenide (GaAs), or the like. Various circuits may be formed on the body. The first connection pads 432 may electrically connect the first semiconductor chip 430 to other components, and a conductive material such as aluminum (Al), or the like, may be used as a material of each of the first connection pads 432.

The first semiconductor chip 430 may be any one of sensor products having a structure in which a sensing region is exposed to the air among sensors used in electronic devices, mobile devices, smartphones, IoT products, or a sensor network device, that is, a chemical sensor detecting chemical substances, particles, or the like, in the air, an image sensor receiving and recognizing light, an optical sensor such as an IR sensor or a UVsensor, a MIC sensor recognizing a user's voice, and a fingerprint sensor analyzing a fingerprint, as an example.

The encapsulant 440 may encapsulate the first connection member 420, the first semiconductor chip 430, and the second semiconductor chip 450. As an example, the encapsulant 440 may serve to protect the first semiconductor chip 430 and the second semiconductor chip 450. An encapsulation form of the encapsulant 440 is not particularly limited, but may be a form in which the encapsulant 440 surrounds at least portions of the first semiconductor chip 430 and the second semiconductor chip 450. For example, the encapsulant 440 may cover at least portions of the first connection member 420, the first semiconductor chip 430, and the second semiconductor chip 450. Certain materials of the encapsulant 440 are not particularly limited. For example, an insulating material may be used as the certain materials of the encapsulant 440. In this case, the insulating material may be a thermosetting resin such as an epoxy resin, a thermoplastic resin such as polyimide, a resin having a reinforcing material such as an inorganic filler impregnated in the thermosetting resin and the thermoplastic resin, for example, ABF, FR-4, BT, a PID resin, or the like. In addition, any known molding material such as an EMC, or the like, may also be used. Alternatively, a resin in which a thermosetting resin or a thermoplastic resin is impregnated together with an inorganic filler in a core material such as a glass fiber (or a glass cloth or a glass fabric) may also be used as the insulating material.

The second semiconductor chip 450 may be disposed in the 1-2-th through-hole 421b of the first connection member 420. In addition, second connection pads 452 for electrical connection to the redistribution module 460 may be provided on an upper surface of the second semiconductor chip 450.

As an example, the second semiconductor chip 450 may be an IC provided in an amount of several hundred to several million or more elements integrated in a single chip, an active element, or the like. The second semiconductor chip 450 may be a semiconductor chip in which an integrated circuit is packaged in a flip-chip form, if necessary. The IC may be, for example, an application processor chip such as a central processor (for example, a CPU), a graphic processor (for example, a GPU), a digital signal processor, a cryptographic processor, a micro processor, a micro controller, or the like, but is not limited thereto.

Meanwhile, the first semiconductor chip module 410 may be manufactured in a PLP manner.

The redistribution module 460 may be disposed on one surface of the first semiconductor chip module 410. As an example, the redistribution module 460 may include insulating layers 462 in which a second through-hole 461 is formed, redistribution layers 463 having portions exposed from the insulating layers 462 and forming at least one layer, and vias 464 connecting the redistribution layers 463 to each other.

In addition, a material of each of the insulating layers 462 may be an insulating material. In this case, a photosensitive insulating material such as a PID resin may also be used as the insulating material. That is, each of the insulating layers 462 may be a photosensitive insulating layer. When the insulating layer 462 has photosensitive properties, the insulating layer 462 may be formed to have a smaller thickness, and a fine pitch of the via 464 may be achieved more easily. Each of the insulating layers 462 may be a photosensitive insulating layer including an insulating resin and an inorganic filler. When the insulating layers 462 are multiple layers, materials of the insulating layers 462 may be the same as each other, and may also be different from each other, if necessary. When the insulating layers 462 are the multiple layers, the insulating layers 462 may be integrated with each other depending on a process, such that a boundary therebetween may also not be apparent.

The redistribution layers 463 may serve to substantially redistribute the first connection pads 432 of the first semiconductor chip 430 and the second connection pads 452 of the second semiconductor chip 450. A material of each of the redistribution layers 463 may be a conductive material such as copper (Cu), aluminum (Al), silver (Ag), tin (Sn), gold (Au), nickel (Ni), lead (Pb), titanium (Ti), or alloys thereof. The redistribution layers 463 may perform various functions depending on designs of corresponding layers. For example, the redistribution layers 463 may include ground patterns, power patterns, signal patterns, and the like. Here, the signal patterns may include various signals except for the ground patterns, the power patterns, and the like, such as data signals, and the like. In addition, the redistribution layers 463 may include various pad patterns, and the like.

In addition, the redistribution layers 463, which are a plurality of layers, may be electrically connected to each other through the vias 464.

Meanwhile, the first semiconductor chip module 410 and the redistribution module 460 may be mechanically coupled to each other by electrical connection structures 480, and the redistribution layer 463 may be electrically connected to at least one of the first wiring layer 423, the first connection pads 432, and the second connection pads 452 by the electrical connection structures 480.

Each of the electrical connection structures 480 may be formed of a low melting point material such as a solder, or the like. However, this is only an example, and a material of each of the electrical connection structures 480 is not particularly limited thereto. The electrical connection structures 480 may be formed as a multilayer or single layer structure. When the electrical connection structures 480 are formed as a multilayer structure, the electrical connection structures 480 may include a copper (Cu) pillar and a solder. When the electrical connection structures 480 are formed as a single layer structure, the electrical connection structures 480 may include a tin-silver solder or copper (Cu). However, this is only an example, and the electrical connection structures 480 are not limited thereto.

The number, an interval, a disposition form, and the like, of electrical connection structures 480 are not particularly limited, but may be sufficiently modified depending on design particulars by those skilled in the art. For example, the electrical connection structures 480 may be provided in an amount of several tens to several thousands according to the number of first connection pads 432 of the first semiconductor chip 430 and the number of second connection pads 452 of the second semiconductor chip 450 or may be provided in an amount of several tens to several thousands or more or several tens to several thousands or less. The electrical connection structures 480 may be solder balls and at least fill openings of the lowermost insulating layer 462 exposing portions of the redistribution layer 463, such that the electrical connection structures 480 may connect the exposed portions of the redistribution layer 463 to the first wiring layer 423 disposed on the upper surface of the first insulating layer 422. Alternatively, when the electrical connection structures 480 are solder balls, the electrical connection structures 480 may cover side surfaces of the redistribution layer 463 and/or the first wiring layer 423 extending onto one surface of a passivation layer (not illustrated), and connection reliability may be more excellent.

At least one of the electrical connection structures 480 may be disposed in a fan-out region. The fan-out region refers to a region except for the region in which the first semiconductor chip 430 is disposed. The fan-out package may have excellent reliability as compared to a fan-in package, may implement a plurality of input/output (I/O) terminals, and may facilitate a 3D interconnection. In addition, as compared to a BGA package, an LGA package, or the like, the fan-out package may be manufactured to have a small thickness, and may have price competitiveness.

Meanwhile, solders 404 for connection to a mainboard (not illustrated) may be formed on the first wiring layer 423 of the first connection member 420 externally exposed from the encapsulant 440.

As described above, the fan-out sensor package 400 may be manufactured by separating manufacturing the first semiconductor chip module 410 and the redistribution module 460 and then coupling the first semiconductor chip module 410 and the redistribution module 460 to each other, and a manufacturing yield of the fan-out sensor package 400 may thus be improved.

Further, the fan-out sensor package 400 may be implemented to have a compact size and a small thickness.

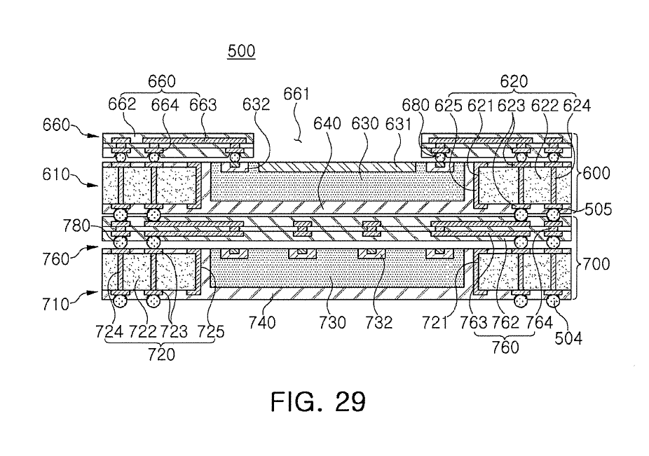

FIG. 29 is a schematic cross-sectional view illustrating a fan-out sensor package according to a fifth exemplary embodiment in the present disclosure.

Referring to FIG. 29, a fan-out sensor package 500 according to a fifth exemplary embodiment in the present disclosure may include a first semiconductor chip package 600 and a second semiconductor chip package 700.

Meanwhile, the first semiconductor chip package 600 may include a first semiconductor chip module 610 and a first redistribution module 660 as an example.

Meanwhile, the first semiconductor chip module 610 and the first redistribution module 660 may be separately manufactured and be then coupled to each other.

The first semiconductor chip module 610 may include a first connection member 620, a first semiconductor chip 630, and a first encapsulant 640 as an example.

A first through-hole 621 in which the first semiconductor chip 630 is disposed may be formed in the first connection member 620. As an example, the first connection member 620 may be provided to support the fan-out sensor package 500, and may maintain rigidity and secure uniformity of a thickness.

In the present exemplary embodiment, side surfaces of the first semiconductor chip 630 may be surrounded by the first connection member 620. However, such a form is only an example and may be variously modified to have other forms, and the first connection member 620 may perform another function depending on such a form.

Meanwhile, a first insulating layer 622 of the first connection member 620 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, ABF, FR-4, a BT resin, or the like, but is not limited thereto. A metal having excellent rigidity and thermal conductivity may be disposed in the first insulating layer 622. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the first insulating layer 622. In addition, the first insulating layer 622 may serve as a support member.

A first wiring layer 623 of the first connection member 620 may be disposed on at least one of an upper surface and a lower surface of the first insulating layer 622. Meanwhile, a plurality of first wiring layers 623 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first wiring layers 623 may be formed by any known method such as electrolytic copper plating, electroless copper plating, or the like. In more detail, the first wiring layers 623 may be formed using a method such as CVD, PVD, sputtering, a subtractive process, an additive process, an SAP, an MSAP, or the like, but are not limited thereto.

Meanwhile, portions of the first wiring layer 623 may be externally exposed.

In addition, first vias 624 of the first connection member 620 may penetrate through the first insulating layer 622 to connect the first wiring layers 623 to each other. In addition, the first vias 624 may be formed of the same material as that of the first wiring layer 623. As an example, a plurality of first vias 624 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The first vias 624 may be formed by any known method such as electrolytic copper plating, electroless copper plating, or the like. In more detail, the first vias 624 may be formed using a method such as CVD, PVD, sputtering, a subtractive process, an additive process, an SAP, an MSAP, or the like, but are not limited thereto.

Meanwhile, a first metal layer 625 of the first connection member 620 may be disposed on at least inner walls of the first through-hole 621. In addition, the first metal layer 625 may extend from the inner walls of the first through-hole 621 and may also be disposed on the upper surface and the lower upper of the first insulating layer 622.

The first metal layer 625 may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof, similar to the first wiring layers 623 and the first vias 624. The first metal layer 625 may be formed by any known method such as electrolytic copper plating, electroless copper plating, or the like. In more detail, the first metal layer 625 may be formed using a method such as CVD, PVD, sputtering, a subtractive process, an additive process, an SAP, an MSAP, or the like, but is not limited thereto.

The first semiconductor chip 630 may have an active surface 633 having a sensing region 631 disposed at a central portion thereof and first connection pads 632 disposed in the vicinity of the sensing region 631 and provided for electrical connection to the first redistribution module 660.

As an example, the first semiconductor chip 630 may be a CIS, but is not limited thereto. The first semiconductor chip 630 may be formed on the basis of an active wafer. In this case, a base material of a body of the first semiconductor chip may be silicon (Si), germanium (Ge), gallium arsenide (GaAs), or the like. Various circuits may be formed on the body. The first connection pads 632 may electrically connect the first semiconductor chip 630 to other components, and a conductive material such as aluminum (Al), or the like, may be used as a material of each of the first connection pads 632.

The first semiconductor chip 630 may be any one of sensor products having a structure in which a sensing region is exposed to the air among sensors used in electronic devices, mobile devices, smartphones, IoT products, or a sensor network device, that is, a chemical sensor detecting chemical substances, particles, or the like, in the air, an image sensor receiving and recognizing light, an optical sensor such as an IR sensor or a UVsensor, a MIC sensor recognizing a user's voice, and a fingerprint sensor analyzing a fingerprint, as an example.

The first encapsulant 640 may encapsulate the first connection member 620 and the first semiconductor chip 630. As an example, the first encapsulant 640 may serve to protect the first semiconductor chip 630. An encapsulation form of the first encapsulant 640 is not particularly limited, but may be a form in which the first encapsulant 640 surrounds at least portions of the first semiconductor chip 630. For example, the first encapsulant 640 may cover at least portions of the first connection member 620 and the first semiconductor chip 630. Certain materials of the first encapsulant 640 are not particularly limited. For example, an insulating material may be used as the certain materials of the first encapsulant 640. In this case, the insulating material may be a thermosetting resin such as an epoxy resin, a thermoplastic resin such as polyimide, a resin having a reinforcing material such as an inorganic filler impregnated in the thermosetting resin and the thermoplastic resin, for example, ABF, FR-4, BT, a PID resin, or the like. In addition, any known molding material such as an EMC, or the like, may also be used. Alternatively, a resin in which a thermosetting resin or a thermoplastic resin is impregnated together with an inorganic filler in a core material such as a glass fiber (or a glass cloth or a glass fabric) may also be used as the insulating material.

Meanwhile, the first semiconductor chip module 610 may be manufactured in a PLP manner.

The first redistribution module 660 may be disposed on one surface of the first semiconductor chip module 610. As an example, the first redistribution module 660 may include second insulating layers 662 in which a second through-hole 661 is formed, first redistribution layers 663 having portions exposed from the second insulating layers 662 and forming at least one layer, and second vias 664 connecting the first redistribution layers 663 to each other.

In addition, a material of each of the second insulating layers 662 may be an insulating material. In this case, a photosensitive insulating material such as a PID resin may also be used as the insulating material. That is, each of the second insulating layers 662 may be a photosensitive insulating layer. When the second insulating layer 662 has photosensitive properties, the second insulating layer 662 may be formed to have a smaller thickness, and a fine pitch of the second via 664 may be achieved more easily. Each of the second insulating layers 662 may be a photosensitive insulating layer including an insulating resin and an inorganic filler. When the second insulating layers 662 are multiple layers, materials of the second insulating layers 662 may be the same as each other, and may also be different from each other, if necessary. When the second insulating layers 662 are the multiple layers, the second insulating layers 662 may be integrated with each other depending on a process, such that a boundary therebetween may also not be apparent.

The first redistribution layers 663 may serve to substantially redistribute the first connection pads 632 of the first semiconductor chip 630. A material of each of the first redistribution layers 663 may be a conductive material such as copper (Cu), aluminum (Al), silver (Ag), tin (Sn), gold (Au), nickel (Ni), lead (Pb), titanium (Ti), or alloys thereof. The first redistribution layers 663 may perform various functions depending on designs of corresponding layers. For example, the first redistribution layers 663 may include ground patterns, power patterns, signal patterns, and the like. Here, the signal patterns may include various signals except for the ground patterns, the power patterns, and the like, such as data signals, and the like. In addition, the first redistribution layers 663 may include various pad patterns, and the like.

In addition, the first redistribution layers 663, which are a plurality of layers, may be electrically connected to each other through the second vias 664.

Meanwhile, the first semiconductor chip module 610 and the first redistribution module 660 may be mechanically coupled to each other by first electrical connection structures 680, and the first redistribution layer 663 may be electrically connected to at least one of the first wiring layer 623 and the first connection pads 632 by the first electrical connection structures 680.

Each of the first electrical connection structures 680 may be formed of a low melting point material such as a solder, or the like. However, this is only an example, and a material of each of the first electrical connection structures 680 is not particularly limited thereto. The first electrical connection structures 680 may be formed as a multilayer or single layer structure. When the first electrical connection structures 680 are formed as a multilayer structure, the first electrical connection structures 680 may include a copper (Cu) pillar and a solder. When the first electrical connection structures 680 are formed as a single layer structure, the first electrical connection structures 680 may include a tin-silver solder or copper (Cu). However, this is only an example, and the first electrical connection structures 680 are not limited thereto.

The number, an interval, a disposition, or the like, of first electrical connection structures 680 are not particularly limited, but may be sufficiently modified by a person skilled in the art depending on design particulars. For example, the first electrical connection structures 680 may be provided in an amount of several tens to several thousands according to the number of first connection pads 632 of the first semiconductor chip 630, or may be provided in an amount of several tens to several thousands or more or several tens to several thousands or less. The electrical connection structures 680 may be solder balls and at least fill openings of the lowermost insulating layer 662 exposing portions of the redistribution layer 663, such that the electrical connection structures 680 may connect the exposed portions of the redistribution layer 663 to the first wiring layer 623 disposed on the upper surface of the first insulating layer 622. Alternatively, when the electrical connection structures 680 are solder balls, the electrical connection structures 680 may cover side surfaces of the first redistribution layer 663 and/or the first wiring layer 623 extending onto one surface of a passivation layer (not illustrated), and connection reliability may be more excellent.

At least one of the first electrical connection structures 680 may be disposed in a fan-out region. The fan-out region refers to a region except for the region in which the first semiconductor chip 630 is disposed. The fan-out package may have excellent reliability as compared to a fan-in package, may implement a plurality of input/output (I/O) terminals, and may facilitate a 3D interconnection. In addition, as compared to a BGA package, an LGA package, or the like, the fan-out package may be manufactured to have a small thickness, and may have price competitiveness.

Meanwhile, solders 505 for connection to the second semiconductor package 700 may be formed on the first wiring layer 623 of the first connection member 620 externally exposed from the first encapsulant 640.

Meanwhile, the second semiconductor chip package 700 may include a second semiconductor chip module 710 and a second redistribution module 760 as an example.

Meanwhile, the second semiconductor chip module 710 and the second redistribution module 760 may be separately manufactured and be then coupled to each other.

The second semiconductor chip module 710 may include a second connection member 720, a second semiconductor chip 730, and a second encapsulant 740 as an example.

A third through-hole 721 in which the second semiconductor chip 730 is disposed may be formed in the second connection member 720. As an example, the second connection member 720 may be provided to support the fan-out sensor package 500, and may maintain rigidity and secure uniformity of a thickness.

In the present exemplary embodiment, side surfaces of the second semiconductor chip 730 may be surrounded by the second connection member 720. However, such a form is only an example and may be variously modified to have other forms, and the second connection member 720 may perform another function depending on such a form.

Meanwhile, a third insulating layer 722 of the second connection member 720 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, ABF, FR-4, a BT resin, or the like, but is not limited thereto. A metal having excellent rigidity and thermal conductivity may be disposed in the third insulating layer 722. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the third insulating layer 722. In addition, the third insulating layer 722 may serve as a support member.

A second wiring layer 723 of the second connection member 720 may be disposed on at least one of an upper surface and a lower surface of the third insulating layer 722. Meanwhile, a plurality of second wiring layers 723 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The second wiring layers 723 may be formed by any known method such as electrolytic copper plating, electroless copper plating, or the like. In more detail, the second wiring layers 723 may be formed using a method such as CVD, PVD, sputtering, a subtractive process, an additive process, an SAP, an MSAP, or the like, but are not limited thereto.

Meanwhile, portions of the second wiring layer 723 may be externally exposed.

In addition, third vias 724 of the second connection member 720 may penetrate through the third insulating layer 722 to connect the second wiring layers 723 to each other. In addition, the third vias 724 may be formed of the same material as that of the second wiring layer 723. As an example, a plurality of third vias 724 may be disposed to be spaced apart from each other, and may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof. The third vias 724 may be formed by any known method such as electrolytic copper plating, electroless copper plating, or the like. In more detail, the third vias 724 may be formed using a method such as CVD, PVD, sputtering, a subtractive process, an additive process, an SAP, an MSAP, or the like, but are not limited thereto.

Meanwhile, a second metal layer 725 of the second connection member 720 may be disposed on at least inner walls of the third through-hole 721. In addition, the second metal layer 725 may extend from the inner walls of the third through-hole 721 and may also be disposed on the upper surface and the lower upper of the third insulating layer 722.

Meanwhile, the second metal layer 725 may include at least one selected from the group consisting of silver (Ag), palladium (Pd), aluminum (Al), nickel (Ni), titanium (Ti), gold (Au), copper (Cu), and platinum (Pt) having excellent conductivity, or mixtures thereof, similar to the second wiring layers 723 and the third vias 724. The second metal layer 725 may be formed by any known method such as electrolytic copper plating, electroless copper plating, or the like. In more detail, the second metal layer 725 may be formed using a method such as CVD, PVD, sputtering, a subtractive process, an additive process, an SAP, an MSAP, or the like, but is not limited thereto.

The second semiconductor chip 730 may be disposed in the third through-hole 721 of the second connection member 720. In addition, second connection pads 732 for electrical connection to the second redistribution module 760 may be provided on an upper surface of the second semiconductor chip 730.

As an example, the second semiconductor chip 730 may be an IC provided in an amount of several hundred to several million or more elements integrated in a single chip, an active element, or the like. The second semiconductor chip 730 may be a semiconductor chip in which an integrated circuit is packaged in a flip-chip form, if necessary. The IC may be, for example, an application processor chip such as a central processor (for example, a CPU), a graphic processor (for example, a GPU), a digital signal processor, a cryptographic processor, a micro processor, a micro controller, or the like, but is not limited thereto.

The second encapsulant 740 may encapsulate the second connection member 720 and the second semiconductor chip 730. As an example, the second encapsulant 740 may serve to protect the second semiconductor chip 730. An encapsulation form of the second encapsulant 740 is not particularly limited, but may be a form in which the second encapsulant 740 surrounds at least portions of the second semiconductor chip 730. For example, the second encapsulant 740 may cover at least portions of the second connection member 720 and the second semiconductor chip 730. Certain materials of the second encapsulant 740 are not particularly limited. For example, an insulating material may be used as the certain materials of the first encapsulant 640. In this case, the insulating material may be a thermosetting resin such as an epoxy resin, a thermoplastic resin such as polyimide, a resin having a reinforcing material such as an inorganic filler impregnated in the thermosetting resin and the thermoplastic resin, for example, ABF, FR-4, BT, a PID resin, or the like. In addition, any known molding material such as an EMC, or the like, may also be used. Alternatively, a resin in which a thermosetting resin or a thermoplastic resin is impregnated together with an inorganic filler in a core material such as a glass fiber (or a glass cloth or a glass fabric) may also be used as the insulating material.

Meanwhile, the second semiconductor chip module 710 may be manufactured in a PLP manner.

The second redistribution module 760 may be disposed on one surface of the second semiconductor chip module 710. As an example, the second redistribution module 760 may include fourth insulating layers 762, second redistribution layers 763 having portions exposed from the fourth insulating layers 762 and forming at least one layer, and fourth vias 764 connecting the second redistribution layers 763 to each other.

In addition, a material of each of the fourth insulating layers 762 may be an insulating material. In this case, a photosensitive insulating material such as a PID resin may also be used as the insulating material. That is, each of the fourth insulating layers 762 may be a photosensitive insulating layer. When the fourth insulating layer 762 has photosensitive properties, the fourth insulating layer 762 may be formed to have a smaller thickness, and a fine pitch of the fourth via 764 may be achieved more easily. Each of the fourth insulating layers 762 may be a photosensitive insulating layer including an insulating resin and an inorganic filler. When the fourth insulating layers 762 are multiple layers, materials of the fourth insulating layers 762 may be the same as each other, and may also be different from each other, if necessary. When the fourth insulating layers 762 are the multiple layers, the fourth insulating layers 762 may be integrated with each other depending on a process, such that a boundary therebetween may also not be apparent.

The second redistribution layers 763 may serve to substantially redistribute the second connection pads 732 of the second semiconductor chip 730. A material of each of the second redistribution layers 763 may be a conductive material such as copper (Cu), aluminum (Al), silver (Ag), tin (Sn), gold (Au), nickel (Ni), lead (Pb), titanium (Ti), or alloys thereof. The second redistribution layers 763 may perform various functions depending on designs of corresponding layers. For example, the second redistribution layers 763 may include ground patterns, power patterns, signal patterns, and the like. Here, the signal patterns may include various signals except for the ground patterns, the power patterns, and the like, such as data signals, and the like. In addition, the second redistribution layers 763 may include various pad patterns, and the like.

In addition, the second redistribution layers 763, which are a plurality of layers, may be electrically connected to each other through the fourth vias 764.

Meanwhile, the second semiconductor chip module 710 and the second redistribution module 760 may be mechanically coupled to each other by second electrical connection structures 780, and the second redistribution layer 763 may be electrically connected to at least one of the second wiring layer 723 and the second connection pads 732 by the second electrical connection structures 780.

Each of the second electrical connection structures 780 may be formed of a low melting point material such as a solder, or the like. However, this is only an example, and a material of each of the second electrical connection structures 780 is not particularly limited thereto. The second electrical connection structures 780 may be formed as a multilayer or single layer structure. When the second electrical connection structures 780 are formed as a multilayer structure, the second electrical connection structures 780 may include a copper (Cu) pillar and a solder. When the second electrical connection structures 780 are formed as a single layer structure, the second electrical connection structures 780 may include a tin-silver solder or copper (Cu). However, this is only an example, and the second electrical connection structures 780 are not limited thereto.

The number, an interval, a disposition, or the like, of second electrical connection structures 780 are not particularly limited, but may be sufficiently modified by a person skilled in the art depending on design particulars. For example, the second electrical connection structures 780 may be provided in an amount of several tens to several thousands according to the number of second connection pads 732 of the second semiconductor chip 730, or may be provided in an amount of several tens to several thousands or more or several tens to several thousands or less. The second electrical connection structures 780 may be solder balls and at least fill openings of the lowermost fourth insulating layer 762 exposing portions of the second redistribution layer 763, such that the second electrical connection structures 780 may connect the exposed portions of the second redistribution layer 763 to the second wiring layer 723 disposed on the upper surface of the third insulating layer 722. Alternatively, when the second electrical connection structures 780 are solder balls, the second electrical connection structures 780 may cover side surfaces of the second redistribution layer 763 and/or the second wiring layer 732 extending onto one surface of a passivation layer (not illustrated), and connection reliability may be more excellent.

At least one of the second electrical connection structures 780 may be disposed in a fan-out region. The fan-out region refers to a region except for the region in which the second semiconductor chip 730 is disposed. The fan-out package may have excellent reliability as compared to a fan-in package, may implement a plurality of input/output (I/O) terminals, and may facilitate a 3D interconnection. In addition, as compared to a BGA package, an LGA package, or the like, the fan-out package may be manufactured to have a small thickness, and may have price competitiveness.

Meanwhile, solders 504 for connection to a mainboard (not illustrated) may be formed on the second wiring layer 723 of the second connection member 720 externally exposed from the second encapsulant 740.

As described above, the first semiconductor chip package 600 and the second semiconductor chip package 700 may be stacked and formed, and the first semiconductor chip 630 and the second semiconductor chip 730 may thus be provided in one package. Therefore, the fan-out sensor package 500 including the first semiconductor chip 630 and the second semiconductor chip 730 and having a subminiature size may be manufactured.

As set forth above, according to an exemplary embodiment in the present disclosure, the fan-out sensor package including the first semiconductor chip may be implemented to have a compact size and a small thickness.

In addition, a manufacturing yield of the fan-out sensor package may be improved.

While exemplary embodiments have been shown and described above, it will be apparent to those skilled in the art that modifications and variations could be made without departing from the scope of the present invention as defined by the appended claims.

What is claimed is:

1. A fan-out sensor package comprising:
a first semiconductor chip module including a first connection member having a first through-hole and a first wiring layer, a first semiconductor chip disposed in the first through-hole and having an active surface on which a sensing region and first connection pads are disposed, and an encapsulant encapsulating at least portions of the first connection member and the first semiconductor chip and filling at least portions of the first through-hole;
a redistribution module having a second through-hole exposing at least a portion of the sensing region and including a redistribution layer; and
electrical connection structures electrically connecting the first wiring layer and the first connection pads to the redistribution layer.

2. The fan-out sensor package of claim 1, wherein the electrical connection structure is made of a low melting point material including a solder.

3. The fan-out sensor package of claim 1, wherein the electrical connection structures are spaced apart from each other.

4. The fan-out sensor package of claim 1, wherein the sensing region of the first semiconductor chip is disposed below the second through-hole of the redistribution module.

5. The fan-out sensor package of claim 1, wherein the first connection member includes:
a first insulating layer in which the first through-hole is formed;
the first wiring layer disposed on at least one of an upper surface and a lower surface of the first insulating layer; and
first vias connected to the first wiring layer.

6. The fan-out sensor package of claim 5, wherein the first connection member further includes a first metal layer disposed on at least inner walls of the first through-hole.

7. The fan-out sensor package of claim 5, wherein the first semiconductor chip module further includes a passive element embedded and disposed in the first connection member.

8. The fan-out sensor package of claim 1, wherein the electrical connection structures are made of a conductive film.

9. The fan-out sensor package of claim 1, wherein the first semiconductor chip has the active surface having the sensing region disposed below the first through-hole and the first connection pads disposed in the vicinity of the sensing region.

10. The fan-out sensor package of claim 1, wherein the redistribution module includes a mesh portion disposed in the second through-hole.

11. The fan-out sensor package of claim 1, wherein the first connection member further includes a third through-hole, and
the first semiconductor chip module further includes a second semiconductor chip disposed in the third through-hole.

12. The fan-out sensor package of claim 11, wherein the redistribution module completely covers an active surface of the second semiconductor chip.

13. The fan-out sensor package of claim 1, wherein the redistribution module covers the first connection pads.

14. A fan-out sensor package comprising:
a first semiconductor chip package; and
a second semiconductor chip package,
wherein the first semiconductor chip package includes:
a first semiconductor chip module including a first connection member having a first through-hole and a first wiring layer, a first semiconductor chip disposed in the first through-hole and having an active surface on which a sensing region and first connection pads are disposed, and a first encapsulant encapsulating at least portions of the first connection member and the first semiconductor chip and filling at least portions of the first through-hole;
a first redistribution module having a second through-hole exposing at least a portion of the sensing region and including a first redistribution layer; and
first electrical connection structures electrically connecting the first wiring layer and the first connection pads to the first redistribution layer, and
wherein the second semiconductor chip package includes:
a second semiconductor chip module including a second connection member having a third through-hole and a second wiring layer, a second semiconductor chip disposed in the third through-hole and having second connection pads disposed on an upper surface thereof, and a second encapsulant encapsulating at least portions of the second connection member and the second semiconductor chip and filling at least portions of the third through-hole;
a second redistribution module including a second redistribution layer; and
second electrical connection structures electrically connecting the second wiring layer and the second connection pads to the second redistribution layer.

15. The fan-out sensor package of claim 14, wherein each of the first and second electrical connection structures is made of a low melting point material including a solder.

16. The fan-out sensor package of claim 14, further comprising third electrical connection structures electrically connecting the first semiconductor chip package and the second semiconductor chip package to each other.
